(19) United States
(12) Patent Application Publication
(10) Pub. No.: US 2025/0237771 A1
(43) Pub. Date: Jul. 24, 2025

(54) NON-TOXIC X-RAY DETECTORS WITH LOW DETECTION LIMITS AND X-RAY PANELS FOR USE IN THE SAME

(71) Applicant: IMPERIAL COLLEGE INNOVATIONS LIMITED, London (GB)

(72) Inventors: Robert A. JAGT, Cambridge (GB); Robert L.Z. HOYE, London (GB); Judith L. MACMANUS-DRISCOLL, Cambridge (GB)

(21) Appl. No.: 18/848,829

(22) PCT Filed: Mar. 21, 2023
(86) PCT No.: PCT/GB2023/050713

§ 371 Date: Sep. 19, 2024

(30) Foreign Application Priority Data
Mar. 21, 2022 (GB) 2203932.5

(51) Int. Cl. G01T 1/24; C01G 29/00; C30B 29/12

(52) U.S. Cl. CPC G01T 1/241; C01G 29/00; C30B 29/12; C01P 2002/60; C01P 2006/10; C01P 2006/60

(57) ABSTRACT

This invention relates to a panel for an X-ray detector comprising a bismuth oxyiodide (BiOI) single crystal material, or a material derived therefrom, as well as a bismuth oxyiodide single crystal material useful in such an X-ray detector, as well as a method for preparing the same. In one aspect, the present invention provides a bismuth oxyiodide (BiOI) single crystal material for use in a panel for an X-ray detector having a length (L) dimension of at least 1 mm, a width (W) dimension of at least 1 mm, and a thickness (T) dimension of at least 0.12 mm.

The invention relates to a panel for an X-ray detector comprising a bismuth oxyiodide (BiOI) single crystal material, or a material derived therefrom, as well as a bismuth oxyiodide single crystal material useful in such an X-ray detector as well as a method for preparing the same.

### BACKGROUND OF THE INVENTION

X-rays are a form of electromagnetic radiation having a wavelength ranging from 10 picometers to 10 nanometers and are widely used for medical imaging (e.g., projectional radiography, computed tomography scans, dentistry). To obtain a medical image using an X-ray and X-ray detector the part of the patient to be X-rayed is placed between the X-ray source and the X-ray detector to produce an image of the internal structure of that particular part of the body. X-rays are partially blocked (“attenuated”) by more dense tissues, such as bone, and may pass more easily through less dense soft tissues. The X-rays that are allowed to pass through lower density soft tissues arrive at the X-ray detector. The pattern of X-rays blocked from reaching the detector by bodily tissues provides the image of the internal structure of that particular part of the body.

However, exposure to X-rays poses a significant health risk as X-rays are a type of ionising radiation which is harmful when absorbed by bodily tissue. Exposure to X-rays thus risks inducing radiation poisoning as well as cancer, especially in the case of repeated exposure, representing a significant risk for both patients and medical practitioners. Whilst the benefits of medical imaging are considered to outweigh the risk of ionising X-ray exposure, there remains a need for methods of X-ray imaging where the dosage of radiation is reduced. For medical imaging applications, the safety threshold is currently a dose rate of 5.5 μGyₐᵢᵣ s⁻¹ (see, Zhang, X. et al. Nucleation-controlled growth of superior lead-free perovskite Cs₃Bi₂I₉ single crystals for high-performance X-ray detection. Nat. Commun. 11, 2304 (2020)). For reference, an acute whole-body exposure of 2 to 6 Gy is usually lethal.

The minimum dosage of radiation necessary to apply to a patient is determined by the detection limit of the X-ray detector, i.e. the lowest detectable dose rate (LoDD). An X-ray detector with a lower detection limit allows for a lower dosage of X-rays to be applied to the tissue of a patient in order to produce a medical image, thus reducing the harmful effects of the X-ray imaging.

X-rays and X-ray detectors are also used in a number of other applications, such as security screening (e.g., at airports), and nuclear security (e.g., checking for radioactive waste in sealed containers). A lower detection limit allows for the detector to be able to detect a radioactive material from greater distance and/or through thicker and/or more radiopaque obstacles. This could allow such detectors to identify potential radioactive waste in hard-to-reach locations or allow potential waste to be contained within more secure vessels with thicker walls that are safer for personnel to handle, but which the monitors can still measure through. X-rays are also useful for materials characterisation (e.g., X-ray diffraction, or measurement of characteristic X-rays to determine composition). A lower detection limit allows for improving the sensitivity of an instrument to low signal peaks, thus improving the accuracy of materials analysis.

Commercial X-ray detectors such as Cd—Zn—Te (CZT) detectors, or thallium doped caesium iodide scintillators suffer drawbacks from the severe toxicity of the cadmium and thallium elements. Furthermore, scintillators have the disadvantage that the light produced after X-ray absorption can get scattered, limiting the spatial resolution of the detector. Additionally, non-scintillation-based methods of directly converting the X-rays into electrical signals traditionally use amorphous selenium as an absorber material. Selenium suffers drawbacks from the limited charge-carrier drift length and low atomic number (i.e., Z number) of selenium which limits the lowest detectable dose rate achievable. Furthermore, selenium is also an environmental hazard as selenium bioaccumulates in aquatic habitats.

Single crystal lead halide perovskite materials are known for use as highly sensitive X-ray detectors, with sensitivity as high as 2.1×10⁴ μC Gyₐᵢᵣ⁻¹ cm⁻² under 8 keV X-ray radiation (see Wei, W. et al. Monolithic integration of hybrid perovskite single crystals with heterogenous substrate for highly sensitive X-ray imaging. Nat. Photonics 11, 315-322 (2017)). However, these materials have less favourable lowest detectable X-ray dosage limits, e.g. 0.4 μGyₐᵢᵣ s⁻¹ (see, Wei, H. et al. Sensitive X-ray detectors made of methylammonium lead tribromide perovskite single crystals, Nat. Photonics 10, 333-339 (2016), and U.S. Pat. No. 10,892,416). Additionally, as would be appreciated, the amount of lead present in these large single crystals significantly exceeds the 0.1 wt. % limit set, for instance, by the EU Restriction of Hazardous Substances directive (RoHS).

The growth of BiOI with BiI₃ and O₂ by chemical vapour deposition has been previously reported in Jagt, R. A, et al. Controlling the preferred orientation of layered BiOI solar absorbers, J. Mater. Chem. C. 8, 10791-10797, (2020). However, chemical vapour deposition methods reported therein provide thin films of BiOI with a thickness of approximately 700 nm, which are unsuitable for use in X-ray detector panels.

Praveenkumar. P, et al. Nanocrystalline bismuth oxyiodides thick films for X-ray detector, Mater. Sci, 104, 104686, (2019), describes the use of nanocrystalline BiOI and Bi₅O₂I thick films for use in X-ray detectors. BiOI nanocrystals were prepared by reaction of Bi(NO₃)₃·5H₂O with KI to yield BiI₃, which was subsequently reacted with water to form BiOI nanocrystals. Praveenkumar. P, et al. reports sensitivities of 1.318 nC mGy⁻¹ cm⁻³ and 1.926 nC/mGy cm⁻³ for thick films of nanocrystalline BiOI (146 μm thickness) and Bi₅O₇I (165 μm thickness), respectively, coated on top of patterned metal electrodes using a slurry deposition process. However, the methods employed by Praveenkumar. P, et al do not afford a BiOI single crystal material. Instead, the authors report that microstructural analysis using SEM confirms the existence of BiOI crystallites (having an average size of 28 nm) in the nanoregime with a flake-like morphology. The present inventors have found that the nanocrystalline form of BiOI disclosed in Praveenkumar. P, et al gives rise to high densities of grain boundaries that scatter electrons and holes, leading to inferior performance when used for an X-ray panel.

The present invention is based on the discovery of the inventors that a single crystal bismuth (III) oxyiodide (BiOI) material with a characteristically low degree of point and line defects may be prepared and advantageously deployed in a highly sensitive X-ray detector with ultralow LoDD, whilst overcoming the above deficiencies associated with known X-ray detector devices.

### SUMMARY OF THE INVENTION

In one aspect, the present invention provides a panel for an X-ray detector comprising a bismuth oxyiodide (BiOI) single crystal material.

In another aspect, the present invention provides a panel for an X-ray detector comprising bismuth oxyiodide (BiOI) in the form of BiOI microcrystals formed from a BiOI single crystal, said microcrystals having a median particle size diameter (d50) of from 1 μm to 1000 μm.

In another aspect, the present invention provides a bismuth oxyiodide (BiOI) single crystal material for use in a panel for an X-ray detector having a length (L) dimension of at least 1 mm, a width (W) dimension of at least 1 mm, and a thickness (T) dimension of at least 0.12 mm.

In another aspect, the present invention provides a bismuth oxyiodide (BiOI) single crystal material for use in a panel for an X-ray detector, the BiOI single crystal material having:
an Urbach energy, determined by measurement of the transmittance by ultraviolet-visible spectrophotometry, of 50 meV or lower, preferably 48 meV or lower, more preferably 46 meV or lower; and/or
a trap state density, as determined through space-charge limited current density measurements, below 10¹⁰ cm⁻³, preferably below 5×10⁹ cm⁻³, more preferably below 3×10⁹ cm⁻³.

In another aspect, the present invention provides a bismuth oxyiodide (BiOI) microcrystal material for use in a panel for an X-ray detector, wherein the BiOI microcrystal material is a pressed pellet comprising BiOI microcrystals, which have optionally undergone sintering, the BiOI microcrystals having a median particle size diameter (d50) of from 1 μm to 1000 μm.

In yet another aspect, the present invention provides a vapour phase crystal growth method for preparing a BiOI single crystal material, said method comprising the steps:
i) providing powders of BiI₃ and Bi₂O₃ together with a transport agent in a sealable growth chamber;
ii) evacuating air from inside the growth chamber, filling the growth chamber with an inert gas, and sealing the growth chamber to form a sealed growth chamber;
iii) heating the contents of the growth chamber to a temperature between 500° C. and 750° C. and maintaining the temperature within this range for at least 48 hours; and
iv) cooling the contents of the growth chamber at a rate of 1° C./min or less.

In yet another aspect, the invention provides a method for preparing a BiOI microcrystalline pressed pellet, said method comprising the steps:
i) providing powders of BiI₃ and Bi₂O₃ together with a transport agent in a sealable growth chamber;
ii) evacuating air from inside the growth chamber, filling the growth chamber with an inert gas, and sealing the growth chamber to form a sealed growth chamber;
iii) heating the contents of the growth chamber to a temperature between 500° C. and 750° C. and maintaining the temperature within this range for at least 48 hours;
iv) cooling the contents of the growth chamber at a rate of 1° C./min or less to provide a BiOI single crystal material;
v) crushing the BiOI single crystal material into a powder having a median particle size diameter (d50) of from 1 μm to 1000 μm; and
vi) pressing the powder, and optionally sintering, into a pellet to form a BiOI microcrystalline pressed pellet.

In yet another aspect, the present invention provides a BiOI single crystal material prepared or preparable by the methods described herein.

In yet another aspect, the present invention provides a BiOI microcrystalline pressed pellet prepared or preparable by the methods described herein.

In yet another aspect, the present invention provides a method for preparing a panel for an X-ray detector, said method comprising depositing first and second electrodes onto a BiOI single crystal material, or a material derived therefrom (e.g. a BiOI microcrystalline material as described herein).

In yet another aspect, the present invention relates to an X-ray detector comprising a panel as described herein.

In yet another aspect, the present invention provides a method of detecting X-rays, said method comprising the steps of:
i) providing an X-ray detector as described herein; and
ii) exposing the X-ray detector to a source of X-rays.

In yet another aspect, the present invention provides use of a BiOI single crystal material, or a material derived therefrom, for the detection of X-rays.

### BRIEF DESCRIPTION OF THE FIGURES

FIG. 1 depicts the stacked I—Bi—O—Bi—I layered structure of crystalline BiOI, with the [a00], [Ob0] and [00c] orientations labelled;

FIG. 2 depicts diagrams of BiOI single crystal material affixed with electrodes in the perpendicular (right) and parallel (left) configuration;

FIG. 3 depicts BiOI single crystals prepared by the methods described herein;

FIG. 4 depicts a BiOI single crystal prepared by the methods described herein;

FIG. 5 depicts an X-ray diffraction pattern of a BiOI single crystal, measured with the scattering vector normal to the c-axis plane;

FIG. 6 depicts the absorption % of a BiOI single crystal of the present invention (slow cooling) compared to a comparative BiOI crystal (fast cooling) at varying energy (in eV);

FIG. 7 depicts the voltage (V) dependent photocurrent of a BiOI single crystal material with electrodes present in the parallel orientation;

FIG. 8 depicts the voltage (V) dependent photocurrent of a BiOI single crystal material with electrodes present in the perpendicular orientation;

FIG. 9 depicts the X-ray sensitivity (μC Gy⁻¹ₐᵢᵣ cm⁻²) as a function of dose rate for a BiOI single crystal material with electrodes present in the parallel orientation and in the perpendicular orientation;

FIG. 10 depicts the signal to noise ratio (SNR) at varying dose rate (nGyₐᵢᵣ s⁻¹) for a BiOI single crystal material with electrodes present in the parallel orientation and in the perpendicular orientation;

FIG. 11 depicts resistivity values, and the current-voltage curves for a BiOI single crystal material with electrodes present in the parallel orientation and in the perpendicular orientation; and

FIG. 12 depicts dark current values from BiOI single crystal devices at different applied bias voltages over time.

### DETAILED DESCRIPTION

The present invention relates to a BiOI single crystal material, or material derived therefrom, having characteristically few point defects and line defects, for use in X-ray detectors, an X-ray detector panel comprising said single crystal material, or material derived therefrom, and processes for the preparation thereof.

In contrast with conventional materials for use in X-ray detectors, BiOI is composed of non-toxic elements and may be grown from non-toxic precursors, BiI₃, Bi₂O₃ and water. Bismuth-based compounds, are used, for example, in cosmetics and over-the-counter stomach medicine. As well as its non-toxicity, BiOI also obviates the use of expensive and rare elements in materials for use in X-ray detectors, which is especially important when large scale production is considered. Additionally, BiOI is stable in ambient air, providing a longer service lifetime for BiOI based detectors.

In one aspect, the present invention provides a panel for an X-ray detector comprising a bismuth oxyiodide (BiOI) single crystal material.

For the avoidance of any doubt, the term “bismuth oxyiodide” used herein refers to bismuth (III) oxyiodide (BiOI) and the term “single crystal” has its usual meaning in the art and refers to a monocrystalline solid in which the crystal lattice is substantially continuous, having no grain boundaries (i.e. no planar defects). As the skilled person will appreciate, a single crystal may still include certain defects (e.g. point defects or line defects), so long as they do not give rise to grain boundaries. A “single crystal material” refers to a substance composed entirely of one single crystal, or a plurality of single crystals that may, for instance, be arranged in a two-dimensional array/grid.

A “material derived therefrom” in the context of the single crystal material of the present invention is a material that may be produced by applying one or more additional process steps to the single crystal material to produce a new BiOI material that may no longer fall within the classical definition of a “single crystal”, for example, due to the introduction of grain boundaries, yet maintains advantageous properties of the single crystal precursor.

The methods described herein are useful in the preparation of a BiOI single crystal having characteristically few point defects and line defects. Conversion of the BiOI single crystal into a polycrystalline form, in particular so as to form BiOI microcrystals (e.g. by crushing and/or grinding of the single crystal), has been found to retain these particular characteristics, despite the introduction of boundaries between crystals in the overall sample. The term “BiOI microcrystals” used herein refers to a plurality of BiOI crystals, formed from a BiOI single crystal, having a median particle size diameter (d50) of from 1 μm to 1000 μm (i.e. micro-scale crystals). The BiOI microcrystals may usefully be pressed and formed into pellets which may then be conveniently deployed in an X-ray panel.

A panel for an X-ray detector is a medical imaging device capable of capturing and converting incident X-ray photons directly into electric charge (so called “direct detection”). The X-rays are absorbed by the X-ray detecting material in the panel, which in the present invention is a BiOI single crystal material, or material derived therefrom. The X-rays ionize electron-hole pairs in the BiOI single crystal material through the photoelectric effect. By applying an external bias across two electrodes in contact with the BiOI single crystal material, the electrons and holes generated are separated through the applied electric field. The generated current is thus proportional to the intensity of the irradiation. An X-ray panel according to the present invention will therefore comprise electrodes in contact with the BiOI single crystal material, or material obtained therefrom, which are configured to detect charge induced in the BiOI single crystal material, or material obtained therefrom, that is proportional to the intensity of X-ray radiation absorbed.

The absorption coefficient, a, for X-ray absorption can be defined as α∝Z⁴/E³ where E is the radiation energy and Z is the effective atomic number of the compound. BiOI has an effective Z value of 73.6 and mass density of 7.92 g/cm³. These values are higher than those of other state of the art X-ray absorber materials, such as CdTe (Z=50.2, mass density=5.85 g/cm³), MAPbI₃ (Z=64.1, mass density=4.5 g/cm³), Cs₂AgBiBr₆ (Z=60.0, mass density=4.65 g/cm³), and (NH₄)₃Bi₂I₉ (Z=62.1, mass density=4.3 g/cm³).

The layered structure of BiOI and its large band gap of 1.93 eV at room temperature enables stable and high resistivity values. Additionally, the high mass density and effective Z number gives rise to high absorption of high energy photons. Photoexcited carriers structurally deform the BiOI lattice due to coupling to the two dominant longitudinal phonon modes, but still form delocalised large polarons. Together with the low effective mass and low defect density, these properties give rise to large mobility lifetime products (μτ) (see, Ganose, A. M, et al. Interplay of Orbital and Relativistic Effects in Bismuth Oxyhalides: BiOF, BiOCl, BiOBr, and BiOI, Chem. Mater. 28, 1980-1984, (2016)).

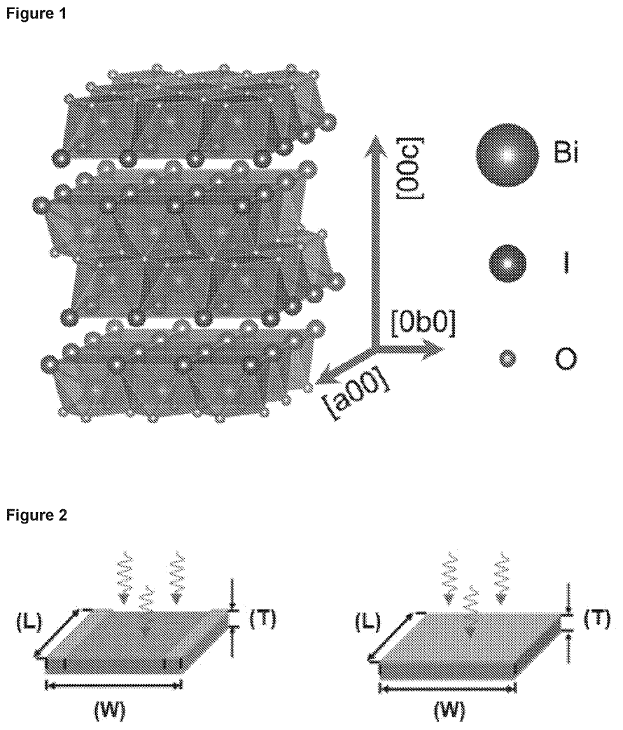

BiOI has a 2D layered structure belonging to the space group P4/nmm, with lattice parameters: a=b=3.99 Å and c=9.17 Å (at room temperature), where the stoichiometric I—Bi—O—Bi—I are stacked along the c axis. A schematic representation of the BiOI crystal structure is shown in FIG. 1. It has been surprisingly discovered that BiOI single crystals useful in accordance with the present invention have a detection limit three orders of magnitude below the current commercial standard for X-ray detectors.

There is no particular limit on the dimensions of the X-ray detector panel (which typically correspond with those of the constituent BiOI single crystal material) that may be used in accordance with the present invention, provided that the BiOI single crystal material component, or material derived therefrom, is capable of absorbing X-rays and undergoing a photoelectric effect to induce a detectable charge. A lab scale X-ray detector panel may, for instance, have a single edge dimension of 5 mm, and a front surface available for detecting X-rays of 20 mm², although much larger panels, for instance, having a single edge dimension of 40 cm, and a front surface available for detecting X-rays of 1280 cm² may be suitable for certain applications. A plurality of single crystals may also be used in an array or grid formation where an X-ray detector requires a larger panel area. Such detector panels comprising an array of single crystals may be used for instance in X-ray computer tomography scanning, or for a standalone X-ray detector for on-site radiation monitoring.

Thus, in some embodiments, the panel for an X-ray detector has a single edge dimension of up to 5 mm and a front surface available for detecting X-rays of up to 20 mm², preferably the panel for an X-ray detector has a single edge dimension of up to 10 mm and a front surface available for detecting X-rays of up to 80 mm², more preferably the panel for an X-ray detector has a single edge dimension of up to 10 cm and a front surface available for detecting X-rays of up to 80 cm², more preferably the panel for an X-ray detector has a single edge dimension of up to 20 cm and a front surface available for detecting X-rays of up to 320 cm², more preferably the panel for an X-ray detector has a single edge dimension of up to 40 cm and a front surface available for detecting X-rays of up to 1280 cm².

The electrodes forming part of the panel may be, for example, deposited on a single surface (e.g. in the form of interdigitated electrodes) of the BiOI single crystal material, or material derived therefrom. Alternatively, the electrodes may, for example, be separately deposited on opposing top and bottom surfaces of the BiOI single crystal material, or material derived therefrom, in a thickness direction, or opposing sides of a thickness edge in proximity of the top and/or bottom surface.

As would be appreciated, crystalline BiOI has a layered crystal structure with stacked I—Bi—O—Bi—I layers along the c axis, as can be seen from FIG. 1. In a preferred embodiment, the electrodes, preferably gold electrodes, are disposed on the BiOI single crystal material, in one of two configurations: i) on the top and bottom surface in a thickness direction (perpendicular configuration), and ii) on opposing sides of a thickness edge proximal the top and/or bottom surface (parallel configuration). In some embodiments, wherein the electrodes, preferably gold electrodes, are disposed in the parallel configuration, the electrodes may be interdigitated electrodes. The width of, and spacing between, the interdigitated electrodes is not particularly limited and may be either consistent or varied, for example, the width of the interdigitated electrodes may be equal to the spacing between the interdigitated electrodes, greater than the spacing between the interdigitated electrodes, or lesser than the spacing between the interdigitated electrodes. In the context of the present invention, perpendicular and parallel configurations are relative to the BiOI layered structure, in which electrons and holes are more mobile in-plane than out of plane. In the perpendicular configuration, these charge-carriers would be transported between stacks of I—O—Bi—O—I, whereas in the parallel configuration, transport is primarily within and moving along each plane of I—O—Bi—O—I. A diagram of BiOI single crystal material affixed with electrodes in the perpendicular (right) and parallel (left) configuration, with the length (L), width (W), and thickness (T) dimensions labelled, can be seen in FIG. 2. Incident X-ray radiation is represented in FIG. 2 by squiggly arrows.

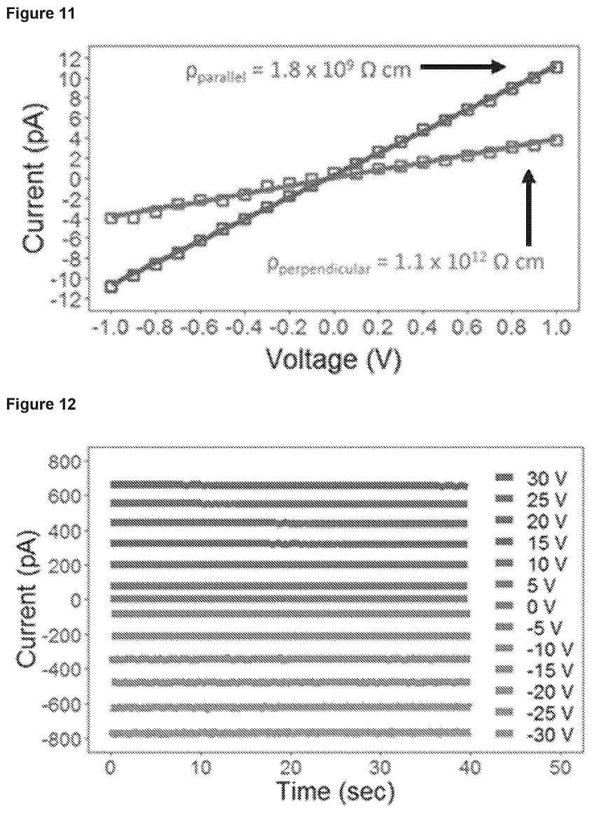

The BiOI single crystal material used in accordance with the present invention has been found to be highly resistive. The resistivity in the perpendicular configuration is 1.1×10¹² Ωcm, and in the parallel configuration is 1.8×10⁹ Ω cm (FIG. 11). As such, the dark currents are low and in the pA range (FIG. 12). The high resistivities are due to the large band gap (1.93 eV) and near intrinsic Fermi-level (Fermi-level to valance band level offset of 0.98 eV), leading to the carrier concentration being low.

The BiOI single crystal has also been found to have a surprisingly high sensitivity. Additionally, configuration of the electrodes in the perpendicular position has been found to provide even greater sensitivity. In a preferred embodiment, the BiOI single crystal material, or material derived therefrom, has an X-ray sensitivity of >500 μC Gy⁻¹ₐᵢᵣ cm⁻², preferably an X-ray sensitivity of >1000 μC Gy⁻¹ₐᵢᵣ cm⁻², using an X-ray dose rate of 440 nGyₐᵢᵣ s⁻¹ to measure the sensitivity. The X-ray sensitivity is readily measured by determining the difference in the photocurrent measured by the detectors, with and without illumination by the X-ray radiation.

Whilst the electrodes may be made from any suitable electrically conductive material, examples of electrode materials include gold (Au), silver (Ag), aluminium (Al), copper (Cu), platinum (Pt), iridium (Ir), iridium oxide (IrO₂), ruthenium (Ru), gallium (Ga), chromium (Cr), lanthanum nikelate (LaNiO₃), strontium ruthenate (SrRuO₃), cobalt (Co), nickel (Ni), palladium (Pd), osmium (Os), rhodium (Rh), carbon (C) or combinations thereof. In preferred embodiments, the electrodes are gold (Au), silver (Ag), aluminium (Al), copper (Cu), platinum (Pt), iridium (Ir), ruthenium (Ru), gallium (Ga), chromium (Cr), cobalt (Co), nickel (Ni), palladium (Pd), osmium (Os), rhodium (Rh), carbon (C) or combinations thereof, most preferably gold (Au).

Preferably, the electrodes will be thin film electrodes which are sufficiently thin so as to avoid attenuating a large proportion of the incident X-ray radiation, particularly when the electrodes are in the parallel configuration. For example, the electrodes have a thickness of from 10 nm to 10000 nm, more preferably from 50 nm to 1000 nm, more preferably from 100 nm to 200 nm. Gold thin film electrodes having a thickness of from 10 nm to 10000 nm, more preferably from 50 nm to 1000 nm, more preferably from 100 nm to 200 nm, are particularly preferred.

The electrodes may be formed using any suitable technique known in the art, such as sputtering, and various forms of physical or chemical vapour deposition techniques (PVD, thermal evaporation, inkjet printing, or CVD), electroplating or any other suitable technique that does not damage the BiOI single crystals. Particular examples thus include ion plating, sol-gel coating, metal evaporation, sputter coating and spin coating, which would be familiar to the skilled person.

In preferred embodiments, the electrodes may be formed using metal evaporation, preferably wherein the electrodes are gold electrodes. Metal evaporation procedures are common in the art and are discussed in detail in the textbook: M. Ohring, (1992), Materials Science of Thin Films, Academic Press, ISBN 9780125249751.

Additional layers may also be present in the detector panel, including insulating, semi-conducting, conducting, and/or passivation layers. Such layers may be provided using any suitable fabrication technique such as, for example, a deposition/machining technique, e.g. sputtering, CVD, PECVD, MOCVD, ALD, laser ablation etc. Furthermore, any suitable patterning technique may be used as required, such as photolithographic techniques (e.g. providing a mask during sputtering and/or etching), also described in the above-mentioned textbook by M. Ohring.

As will be appreciated by the skilled person, the X-ray detector panel may also include integrated circuitry (e.g. a read out integrated circuit) to extract and process X-ray induced signals, typically by means of a thin film transistor array (TFT), in order to generate a digital X-ray image. Such read out circuits are well known by the skilled person and those that are commercially available for conventional direct detection X-ray panels can be readily utilised in connection with X-ray panels according to the present invention.

In some embodiments, a panel for an X-ray detector comprising a BiOI single crystal material may comprise one or more BiOI single crystals wherein one or more of the single crystals has the dimensions of at least 1 mm, a width (W) dimension of at least 1 mm, and a thickness (T) dimension of at least 0.05 mm, and preferably wherein L is from 1 to 1000 mm; W is from 1 to 1000 mm; and T is from 0.05 to 10 mm; preferably wherein L is from 2 to 500 mm; W is 2 to 500 mm, and T is 0.06 to 0.14 mm.

In a preferred embodiment, the BiOI single crystal has a length (L) dimension of at least 1 mm, a width (W) dimension of at least 1 mm, and a thickness (T) dimension of at least 0.05 mm. In a more preferred embodiment L is from 1 to 1000 mm; W is from 1 to 1000 mm; and T is from 0.05 to 10 mm; preferably wherein L is from 2 to 500 mm; W is 2 to 500 mm, and T is 0.06 to 0.14 mm.

In another aspect, the X-ray detector panel may comprise BiOI in the form of BiOI microcrystals formed from a BiOI single crystal, said microcrystals having a median particle size diameter (d50) of from 1 μm to 1000 μm. In some embodiments, BiOI microcrystals may be formed into a pressed pellet comprising BiOI microcrystals. Methods of forming pressed pellets would be within the capabilities of the skilled person, and typically involve incorporating a powder of the BiOI microcrystals into a powder press die of a desired shape and dimension and pressing, and optionally sintering through simultaneous exposure to heat (preferably in a controlled inert-gas environment), to form a pellet, as discussed in more detail herein. For example, a pressed pellet may be formed using an Atlas (RTM) Manual 15 Ton (15 T) and 25 Ton (25 T) Hydraulic Press, as per the instructions provided in the Atlas (RTM) Manual 15 Ton (15 T) and 25 Ton (25 T) Hydraulic Press: User Manual, 2I-15011 Issue 14. Another suitable method of pressed pellet formation, that may be used with the present invention is outlined in Forth. L. J. et al. Sensitive X-ray Detectors Synthesised from CsPbBr₃, 2019 IEEE Nuclear Science Symposium and Medical Imaging Conference, Manchester, UK, (NSS/MIC).

As would be appreciated, a BiOI microcrystalline material in the form of a pressed pellet comprises a plurality of crystals at random orientations and thus the electrodes cannot be disposed at a specific orientation with regard to the BiOI crystal structure, when deposited on the BiOI microcrystalline material. A BiOI microcrystalline pressed pellet, which is derived from a BiOI single crystal, is of particular use in larger panels and for scaled up production because smaller sized single crystals can be prepared in less time and subsequently converted into BiOI microcrystals.

The BiOI pressed pellet comprises air gaps and/or grain boundaries between the BiOI microcrystals. As would be appreciated, air gaps between the BiOI microcrystals would contribute towards porosity of the pressed pellet. A lower degree of compression, as well as compression at a cooler temperature will contribute towards a BiOI pressed pellet comprising a higher degree of air gaps and porosity. Higher pressure compression and/or compression at higher temperature will encourage the microcrystals to diffuse and grow into any air gaps between microcrystals, reducing the porosity and concentration of air gaps. Forming the pressed pellet under high pressure and/or under high temperature contributes towards reducing porosity and thus minimising the concentration of air gaps. As the microcrystals diffuse and grow into any air gaps between microcrystals, this increases the concentration of points of contact between microcrystals and thus increases the concentration of grain boundaries between the microcrystals. Thus, the concentration of grain boundaries in a pressed pellet is inversely proportional to the concentration of air gaps.

The porosity, and thus the concentration of air gaps may also be reduced or eliminated by sintering and/or further compression of the pressed pellet after its initial preparation.

The BiOI single crystal material preparable by the methods described hereinbelow have enhanced purity and fewer defects in their crystalline structure than BiOI materials known in the prior art. The BiOI single crystal material of the present invention therefore has a number of desirable properties that make it particularly suited for use as an X-ray detector material in a panel for an X-ray detector. The low density of defects in the single crystal material can also be taken advantage of when the single crystals are converted into microcrystalline form, which has been found to be useful in some aspects of the invention, where for instance the BiOI is provided as a pressed pellet. Thus, although forming a microcrystalline pressed pellet may introduce structural defects into the material in the form of air gaps and/or grain boundaries, the low defect density of the starting material may ensure the density of these structural defects introduced remains relatively low. These benefits are in addition to low-toxicity as discussed herein.

Whilst materials comprising BiOI microcrystals derived from a BiOI single crystal material as described herein, may have an increased concentration of certain defects as compared to said BiOI single crystal material itself, the materials comprising BiOI microcrystals derived from a BiOI single crystal material as described herein will still enjoy a significantly lower concentration of defects overall, as compared to a comparative material comprising BiOI microcrystals that were derived from any previously known BiOI single crystal having a higher degree of defects. This is because defects from the precursor BiOI single crystal or single crystal material will persist in any material formed therefrom.

Of the forms of defects that may be present in the microcrystalline material obtained from the BiOI single crystal material, defects in the form of air gaps are the least preferred, and less so, for instance, than grain boundaries. Therefore, in preferred embodiments, the BiOI microcrystalline pressed pellet has a reduced or eliminated porosity and concentration of air gaps, which may for instance be achieved by pressing at high pressure and/or sintering.

The BiOI single crystal material used in accordance with the present invention suffers from a surprisingly low degree of self-trapping. This is because the photogenerated charge-carriers primarily couple to longitudinal optical (LO) phonons rather than to acoustic phonons, thus giving rise to large polarons instead of localised small polarons or self-trapped excitons. This allows high mobilities reaching 83 cm² V⁻¹ s⁻¹ to be achieved, enabling long drift lengths that allow the photo-generated charge carriers to be extracted from the electrodes. Another important contributor to the high mobilities is the low trap density, which minimise carrier scattering. In some embodiments, the BiOI single crystal material, or material derived therefrom, has a trap state density below 10¹⁰ cm⁻³, as determined through space-charge limited current density measurements, preferably below 7×10⁹ cm⁻³, more preferably below 5×10⁹ cm⁻³, even more preferably below 3×10⁹ cm⁻³.

The mobility-lifetime product is a key parameter, which characterizes the quality of semiconductor radiation detectors. It is routinely evaluated via the Hecht equation. This product is determined by fitting the Hecht equation to the photocurrent from the X-ray detector under different applied biases. In a preferred embodiment, the BiOI single crystal material, or material derived therefrom, has a mobility-lifetime product of at least 3.0×10⁻² cm² V⁻¹, preferably at least 5.0×10⁻² cm² V⁻¹.

Additionally, the BiOI single crystal has been found to have a surprisingly low lowest detectable dose rate (LoDD). Additionally, the configuration of the electrodes in the perpendicular position has been found to provide even lower LoDD. This is due to the perpendicular configuration having higher resistivities and lower dark currents. In a preferred embodiment, the BiOI single crystal material, or material derived therefrom, has a LoDD rate for Cu K_{α} X-rays from 1 to 5 nGyₐᵢᵣ s⁻¹, preferably from 1 to 3 nGyₐᵢᵣ s⁻¹. The LoDD is determined by measuring the signal to noise ratio (SNR) of the detectors over a range of X-ray dose rates and extrapolating the photocurrent down to a SNR of 3, which is the standard approach.

Additionally, the BiOI single crystal has also been found to have a surprisingly high sub-bandgap absorption, as measured by photothermal deflection spectroscopy. In a preferred embodiment, the BiOI single crystal material, or material derived therefrom, has a sub-bandgap absorption of from 5% to 0%, preferably from 4% to 0%, more preferably from 3% to 0%, more preferably from 2% to 0%, more preferably from 1% to 0%, most preferably 0%.

In yet another aspect, the present invention provides a BiOI single crystal material prepared or preparable by the methods described herein. The methods described herein prepare BiOI single crystal material with characteristically few point or line defects. The extent of defects, including point or line defects, present in a BiOI single crystal can be determined by measuring its Urbach energy (E_{U}) which is used to quantify disorder in the material that is manifest as a tail of states extending from the band edges of the semiconductor. In a preferred embodiment, the BiOI single crystal material prepared or preparable by the methods described herein has an Urbach energy, determined by measurement of the transmittance by ultraviolet-visible spectrophotometry, of 50 meV or lower, 49 meV or lower, 48 meV or lower, 47 meV or lower, 46 meV or lower, or even 45 meV or lower. For example, the Urbach energy, determined by measurement of the transmittance by ultraviolet-visible spectrophotometry, may be from 45 meV to 50 meV, preferably from 45 to 49 meV, more preferably from 45 to 48 meV, even more preferably from 45 to 47 meV, and most preferably from 45 to 46 meV.

The Urbach energy is determined by fitting precise measurements of the absorption onset of the material with the equation:

$$α = {α}_{0} exp ( \frac{hv - {E}_{g}}{{E}_{U}} ) ,$$

where α is the absorption coefficient, α₀ the pre-exponential constant, hv the photon energy, E_{g} the bandgap and E_{U} the Urbach energy. Standard approaches include measuring the transmittance of the single crystal or using highly-sensitive photothermal deflection spectroscopy. Measurement of the Urbach energy of a given BiOI single crystal would be within the capabilities of the skilled person, and typically involve measurement of the absorption coefficient using the constant photocurrent method (CPM) or measurement of the transmittance by ultraviolet-visible spectrophotometry.

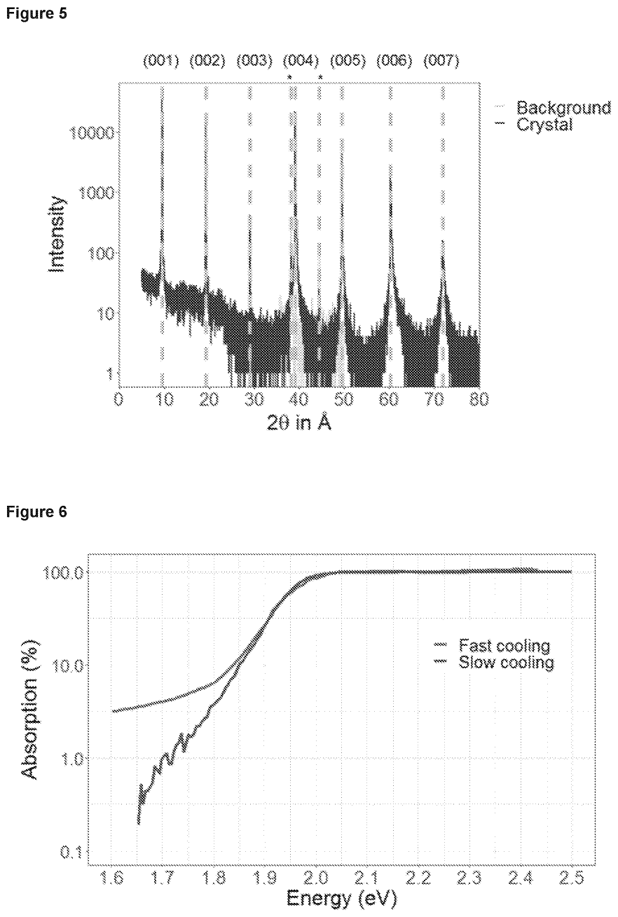

In another aspect, the BiOI single crystal material prepared or preparable by the methods described herein is characterised by the diffraction pattern shown in FIG. 5, using Cu K_{α} radiation as the X-ray source.

In one aspect, the present invention provides a vapour phase crystal growth method for preparing a BiOI single crystal material, said method comprising the steps:
i) providing powders of BiI₃ and Bi₂O₃ together with a transport agent in a sealable growth chamber;
ii) evacuating air from inside the growth chamber, filling the growth chamber with an inert gas, and sealing the growth chamber to form a sealed growth chamber;
iii) heating the contents of the growth chamber to a temperature between 500° C. and 750° C. and maintaining the temperature within this range for at least 48 hours; and
iv) cooling the contents of the growth chamber at a rate of 1° C./min or less.

The production of BiOI single crystals from BiI₃ and Bi₂O₃ has been demonstrated using chemical vapour transport, (see, Oppermann, H, et al. Zum chemischen Transport von Bismutoxidhalogeniden BiOX (X=Cl, Br, I) mit Halogen, Halogenwasserstoff sowie Wasser und Bestimmung der Molwärmen von BiOX, Z. Anorg, Allg, Chem. 626, 937-946, (2000)). This paper studies the thermodynamic behaviour of bismuth oxyhalides, including bismuth oxyiodide, in combination with various chemical vapour transport agents and conditions. It is shown that chemical vapour transport can be used to prepare a thin single crystal “leaf” of BiOI. However, Oppermann, H, et al. is directed towards study of the transport mechanism and does not consider interrogate purity or level of defects present in the resulting BiOI single crystals.

In some embodiments, heating the contents of the growth chamber to a temperature between 500° C. and 750° C. and maintaining the temperature within this range for at least 48 hours occurs in a two-zone reactor, wherein the two zones have different temperatures, for example a two-zone furnace, such as a two-zone tube furnace. A two-zone reactor comprises a first source zone having a relatively higher temperature and second growth zone having a relatively lower temperature. The vapour phase is free to move around the growth chamber and will migrate from the source zone having a relatively higher temperature to the growth zone having a relatively lower temperature. The starting material for the reaction begins in the source zone, over the course of the reaction the crystalline product is formed in the growth zone.

The difference in temperature between the two zones impacts the size of the crystal that is formed. A larger delta in temperature than 40° C. will provide smaller crystals, whereas a delta in temperature lesser than 40° C. will provide larger crystals. The difference in temperature between the first source zone having a relatively higher temperature and second growth zone having a relatively lower temperature can be adapted to the desired crystal size. In some embodiments the difference in temperature between the two zones is from 1° C. to 250° C., preferably from 2° C. to 200° C., more preferably from 3° C. to 180° C., even more preferably from 5° C. to 160° C., even more preferably from 10° C. to 140° C., even more preferably from 15° C. to 120° C., even more preferably from 20° C. to 100° C., even more preferably from 25° C. to 80° C., even more preferably from 30° C. to 60° C., even more preferably from 35° C. to 50° C., for example 40° C.

In some embodiments, for example where a larger crystal is desired, the difference in temperature between the two zones is 40° C. or less, preferably 35° C. or less, more preferably 30° C. or less, even more preferably 25° C. or less, even more preferably, 20° C. or less, even more preferably 15° C. or less, even more preferably 10° C. or less, even more preferably 5° C. or less, even more preferably 3° C. or less, even more preferably 2° C. or less, most preferably 1° C. or less.

In some embodiments, for example where a smaller crystal is desired, the difference in temperature between the two zones is at least 40° C., preferably at least 50° C., more preferably at least 60° C., even more preferably at least 80° C., even more preferably at least 100° C., even more preferably at least 120° C., even more preferably at least 140° C., even more preferably at least 160° C., even more preferably at least 180° C., even more preferably at least 200° C., most preferably at least 250° C.

In some embodiments, the temperature in the growth zone is maintained at from 500° C. to 700° C., preferably from 670° C. to 690° C., for example from 675° C. to 685° C. In some embodiments the temperature in the source zone is maintained at from 700° C. to 750° C., preferably from 710° C. to 730° C., for example from 715° C. to 725° C.

The temperature of the contents of the growth chamber, in step iii) is maintained within the desired range for at least 48 hours. Longer durations of heating have been found to produce larger crystals. Thus, in some embodiments, for example where larger crystals are desired, the temperature of the contents of the growth chamber, in step iii) is maintained within the desired temperature range for at least 72 hours, preferably at least 96 hours, more preferably at least 120 hours, even more preferably at least 144 hours, most preferably 168 hours. Whilst an upper limit to this time period is not essential, in some embodiments the temperature of the contents of the growth chamber, in step iii) is maintained within the desired temperature range for from 48 hours to 168 hours, preferably from 48 hours to 144 hours, more preferably from 72 hours to 144 hours, most preferably from 96 to 144 hours.

In a preferred embodiment, wherein the two-zone reactor comprises a source zone having a relatively higher temperature and growth zone having a relatively lower temperature, the ramp up rate of the temperature of the source zone is lower than that of the ramp up rate of the temperature of the growth zone, such that the temperature of the source zone is initially lower than that of the growth zone, but the temperature of the source zone is higher than the temperature of the growth zone once ramping up is complete and a temperature is maintained as per step iii).

In some embodiments the temperature of the contents of the growth chamber is increased, in step iii) with a ramp up rate of from 0.1° C./min to 10° C./min, preferably from 0.5° C./min to 5° C./min, more preferably from 1° C./min to 3° C./min, most preferably from 1.5° C./min to 2.5° C./min. In some embodiments the ramp up rate is the same in the source zone and the growth zone. In other embodiments the ramp up rate is not the same in the in the growth zone and the growth zone, preferably wherein the ramp up rate is lower in the source zone than in the growth zone. Different ramp up rates for the two zones can be achieved using, for example, a two-zone furnace.

In a preferred embodiment, the temperature of the source zone is increased, in step iii) with a ramp up rate of from 0.1° C./min to 10° C./min, preferably from 0.3° C./min to 5° C./min, more preferably from 0.5° C./min to 3° C./min, most preferably from 0.8° C./min to 2° C./min. In a preferred embodiment, the temperature of the growth zone is increased, in step iii) with a ramp up rate of from 0.1° C./min to 10° C./min, preferably from 0.5° C./min to 5° C./min, more preferably from 1° C./min to 3° C./min, most preferably from 1.5° C./min to 2.5° C./min.

In a more preferred embodiment, the temperature of the source zone is increased, in step iii) with a ramp up rate of from 0.1° C./min to 10° C./min and the temperature of the growth zone is increased, in step iii) with a ramp up rate of from 0.1° C./min to 10° C./min, preferably the ramp up rates are from 0.3° C./min to 5° C./min and from 0.5° C./min to 5° C./min respectively, more preferably the ramp up rates are from 0.5° C./min to 3° C./min and 1° C./min to 3° C./min respectively, even more preferably the ramp up rates are from 0.8° C./min to 2° C./min and from 1° C./min to 3° C./min respectively.

Various transport agents are suitable for use in the present invention. In a preferred embodiment the transport agent is selected from H₂O, H₂, I₂, Br₂, Cl₂, Se, SeCl₄ and TeCl₄, in a more preferred embodiment the transport agent is selected from H₂O, Cl₂, Br₂, and I₂, in an even more preferred embodiment the transport agent is H₂O.

In a preferred embodiment, the BiI₃ and Bi₂O₃ powders together with the transport agent, are provided in the form of a compressed pellet in step i). Methods of compressing powdered material into a pellet are known to the skilled person. An example of which is use of a press, such as a hydraulic press.

Powders of BiI₃ and/or Bi₂O₃ according to the present invention have a median particle size diameter (d50) of less than 1000 μm, preferably less than 800 μm. Examples of suitable median particle size diameters (d50) for powders useful in the present invention include, less than 700 μm, less than 600 μm or less than 500 μm. In preferred embodiments, BiI₃ and/or Bi₂O₃ powder useful in the present invention has a median particle size diameter (d50) of from 10 to 700 μm, preferably from 20 μm to 600 μm, more preferably from 50 μm to 500 μm, or most preferably from 100 μm to 300 μm. In some embodiments, BiI₃ and/or Bi₂O₃ powder useful in the present invention has a median particle size diameter (d50) of less than 10 μm. Particle size diameter (d50) may suitably be determined by means of a laser diffraction particle size analyser (e.g. a Microtrac S3500 Particle size analyser). Pellets referred to herein correspond to a compressed form of the BiI₃ and Bi₂O₃ powder and transport agent described above. A pellet may be formed into a variety of shapes, including disc, cylindrical or capsular shapes.

Typically, BiI₃ and Bi₂O₃ will be used in an equimolar ratio, i.e. a 1:1 molar ratio. However, non-equimolar ratios of BiI₃ and Bi₂O₃ may also be used. In some embodiments the molar ratio of BiI₃ and Bi₂O₃ may be 3:1, preferably 2:1, more preferably 1.5:1, even more preferably 1.25:1, even more preferably 1.1:1, even more preferably 1.05:1, and most preferably 1:1. In some embodiments the molar ratio of BiI₃ and Bi₂O₃ may be 1:3, preferably 1:2, more preferably 1:1.5, even more preferably 1:1.25, even more preferably 1:1.1, even more preferably 1:1.05, and most preferably 1:1.

The sealable growth chamber is any vessel capable of being hermetically sealed and that is sufficiently inert to the given reaction conditions and temperature. Examples of suitable sealable growth chambers include ampoules, crucibles, or tubes, typically made from glass, quartz or borosilicate glass. The growth chamber may be reusable or single use. In a preferred embodiment, the growth chamber used is an ampoule that is sealed using a flame torch. In some embodiments, a sealable growth chamber, for example, an ampoule, crucible, or tube, particularly those made of glass, may contain trace moisture that is sufficient to act as the transport agent. However, it would also be possible in other embodiments, to dry the sealable growth chamber, by methods known in the art, such as flame drying, or desiccation, where an alternative transport agent other than water is used.

Whilst any inert gas may be used to fill the growth chamber, nitrogen or argon are typically used due to their relative abundance.

In some embodiments the growth chamber is filled with an amount of inert gas and sealed such that the pressure of the inert gas inside the sealed growth chamber is lower than atmospheric pressure, at room temperature before heating in step iii) takes place. In a preferred embodiment, the pressure inside the sealed growth chamber is 90 kPa or lower, preferably 80 kPa or lower, more preferably 70 kPa or lower, even more preferably 60 kPa or lower, even more preferably 50 kPa or lower, even more preferably 40 kPa or lower, even more preferably 30 kPa or lower, even more preferably 20 kPa or lower, even more preferably 20 kPa or lower, even more preferably 5 kPa or lower, even more preferably 3 kPa or lower, even more preferably 2 kPa or lower, even more preferably 1 kPa or lower, even more preferably 0.1 kPa or lower, even more preferably 0.01 kPa or lower, even more preferably 1 Pa or lower, even more preferably 0.1 Pa or lower, even more preferably 0. 01 Pa or lower, most preferably 0.001 Pa or lower.

The cooling rate in step iv) is of critical importance to the nature of the crystals produced by this method, with slow cooling rates contributing towards higher crystal surface quality, smoothness, and a reduction in thermodynamic defects. Upon cooling of the crystal, the concentration of point defects and line defects decreases. However, if cooling is too rapid, point defects and line defects may become frozen in and incorporated into the crystal.

Without being bound by any specific theory, the rate of cooling is approximately correlated with the concentration of point and line defects present in the resulting single crystal. This decrease in concentration of point and line defects can be quantified by measuring the Urbach energy or the trap state density of the single crystal. BiOI single crystals prepared by the methods described herein are therefore characterised by a low concentration of point and line defects, and a correspondingly low Urbach energy and trap state density. These properties make them particularly well suited as an X-ray detecting material, for use in a panel for an X-ray detector.

A slow cooling rate of 1° C./min or less, is required in order to prepare crystals of high quality and few point or line defects that are useful as X-ray detectors. In a preferred embodiment, the cooling rate in step iv) is 1° C./min or less, preferably 0.9° C./min or less, more preferably 0.8° C./min or less, even more preferably 0.7° C./min or less, even more preferably 0.6° C./min or less, even more preferably 0.5° C./min or less, even more preferably 0.4° C./min or less, even more preferably 0.3° C./min or less, even more preferably 0.2° C./min or less, even more preferably 0.19° C./min or less, even more preferably 0.18° C./min or less, even more preferably 0.17° C./min or less, even more preferably 0.16° C./min or less, even more preferably 0.15° C./min or less, even more preferably 0.14° C./min or less, even more preferably 0.13° C./min or less, even more preferably 0.12° C./min or less, even more preferably 0.11° C./min or less, even more preferably 0.10° C./min or less, even more preferably 0.09° C./min or less, even more preferably 0.08° C./min or less, even more preferably 0.07° C./min or less, even more preferably 0.06° C./min or less, even more preferably 0.05° C./min or less, even more preferably 0.04° C./min or less, even more preferably 0.03° C./min or less, even more preferably 0.02° C./min or less, most preferably 0.01° C./min or less. Whilst a lower limit to cooling rate is not essential so long as the cooling rate is greater than zero, in some embodiments, the cooling rate in step iv) is from 1° C./min to 0.001° C./min, preferably from 0.5° C./min to 0.01° C./min, more preferably from 0.2° C./min to 0.01° C./min.

In some applications of the invention, a cooling rate of 0.2° C./min or less, or of from 0.2° C./min to 0.01° C./min may be a particularly suitable compromise between the advantages provided by a slow rate of cooling and the commercial need for more rapid production of BiOI single crystal material, or a material derived therefrom.

In the context of the present invention, the term cooling herein refers to reducing the temperature, typically to ambient temperature of from 15 to 25° C., or to a temperature at which the BiOI single crystal produced may be further processed as, for instance, part of converting to a microcrystalline form, as in some aspects of the invention.

An example of a suitable vapour phase crystal growth method is chemical vapour transport. Chemical vapour transport is a vapour phase crystal growth method involving the reversible conversion of one or more solid compound into volatile derivatives at elevated temperature in a sealed growth chamber, which can migrate in the vapour phase. The vapour phase material reverts to its solid phase as it is allowed to cool from the elevated temperature. Chemical vapour transport involves a transport agent which is a volatile substance at the reaction temperature, which vaporises, or contributes towards vaporising the one or more solid compound. When the vapour phase material reverts to its solid phase, a crystal of the original solid material is grown. Chemical vapour transport is therefore useful in preparing crystalline materials from amorphous solids or smaller crystals as well as solid precursors. In a preferred embodiment the vapour phase crystal growth method for preparing a BiOI single crystal material is a chemical vapour transport method.

Some chemical vapour transport reactions may include auto transport, where one or more solid compound or one or more decomposition product thereof is transferred to the vapour phase at elevated temperature without the addition of an external transport agent. Wherein the one or more solid compound or one or more decomposition product thereof, reverts to its solid phase, and its original chemical species in the case of a decomposition product.

Another example of a vapour phase crystal growth method using a two-zone furnace that may be used for preparing a BiOI single crystal material is an adapted Bridgman-Stockbarger method. In this method, a seed crystal is used, and a single crystal of the same crystallographic orientation as the seed material is grown on the seed and is progressively formed along the length of the container. The process can be carried out in a horizontal or vertical orientation, and typically involves a rotating crucible or ampoule. In some embodiments, a seed crystal may be present in the growth zone. As the seed crystal is not essential, a seed crystal for use in the present method could first be prepared by the same method without a seed crystal. In some embodiments, the growth chamber may be in a horizontal or vertical orientation. In some embodiments, the growth chamber may be rotated or otherwise agitated. As would be appreciated, chemical vapour transport methods can be scaled up depending on the amount of crystal to be produced. Bridgman-Stockbarger method is particularly well suited to larger scale production.

In another aspect, the invention provides a method for preparing a BiOI microcrystalline pressed pellet, said method comprising the steps:
i) providing powders of BiI₃ and Bi₂O₃ together with a transport agent in a sealable growth chamber;
ii) evacuating air from inside the growth chamber, filling the growth chamber with an inert gas, and sealing the growth chamber to form a sealed growth chamber;
iii) heating the contents of the growth chamber to a temperature between 500° C. and 750° C. and maintaining the temperature within this range for at least 48 hours;
iv) cooling the contents of the growth chamber at a rate of 1° C./min or less to provide a BiOI single crystal material;
v) crushing the BiOI single crystal material into a powder having a median particle size diameter (d50) of from 1 μm to 1000 μm; and
vi) pressing, and optionally sintering, the powder into a pellet to form a BiOI microcrystalline pressed pellet.

As the BiOI microcrystalline pressed pellet is derived from a BiOI single crystal material prepared by steps i) to iv) of the above-described vapour phase crystal growth method for preparing a BiOI single crystal material, any of the embodiments of the above-described vapour phase crystal growth method for preparing a BiOI single crystal material may also be used in steps i) to iv) of the method for preparing a BiOI microcrystalline pressed pellet. For example, any combination of the above discussed apparatus, heating rates, cooling rates, growth zone and source zone temperatures, growth time, transport agents, etc, that may be utilised in connection with the previous aspect may also be utilised in connection with the present aspect.

A BiOI microcrystalline pellet is a pellet comprising, consisting essentially of, or consisting of BiOI single crystals having a median particle size diameter (d50) of from 1 μm to 1000 μm, i.e. microcrystals. The pellet is not particularly limited in its dimensions and may be formed into any desired shape and size. Typically, the pellet is formed into a shape and size corresponding to the size of the panel of an X-ray detector, or a shape and size suitable for incorporation into an array of pellets for a panel of an X-ray detector.

A pressed BiOI microcrystalline pellet may be formed, for example, by grinding a BiOI single crystal material into a powder having a median particle size diameter (d50) of from 1 μm to 1000 μm, preforming the powder into the desired shape and size using a compressor followed by compaction by powder pressing, for example 0.2 GPa. Many methods of powder compaction would be known to the skilled person and may also be used to press the powder into a pellet, for example, die pressing, cold isostatic pressing, hot isostatic pressing, or shock (dynamic) consolidation. In a preferred embodiment, the method for preparing a BiOI microcrystalline pressed pellet further comprises the step of sintering the BiOI microcrystalline pressed pellet to reduce or eliminate its porosity (i.e. to reduce or eliminate air gaps).

The typical temperatures used for sintering are around ⅔ of a material's melting temperature. Preferably, sintering comprises heating the BiOI microcrystalline pressed pellet from 400° C. to 800° C., preferably from 400° C. to 600° C., more preferably from 400° C. to 500° C. Sintering may also be performed simultaneously with certain methods of powder compaction. Any additional sintering step subsequent to step vi) may also be performed under pressure.

Standard methods of grinding a BiOI single crystal material into a powder having a median particle size diameter (d50) of from 1 μm to 1000 μm would also be known to the skilled person, for example, ball milling, hand grinding or mechanical grinding. These processes are well known in the art and can be performed with commercially available machinery such as grinder mills, or commercial mechanical or hand grinders. Particle size diameter (d50) may suitably be determined by means of a laser diffraction particle size analyser (e.g. a Microtrac S3500 Particle size analyser).

In some embodiments, the method involves in step v), crushing the BiOI single crystal material into a powder having a median particle size diameter (d50) of from 3 μm to 900 μm, preferably from 5 μm to 800 μm, more preferably from 20 μm to 700 μm, even more preferably from 30 μm to 600 μm, even more preferably 50 μm to 500 μm.

The resulting microcrystalline pellet will be made up of BiOI single crystals as described herein, having a median diameter of from 1 μm to 1000 μm. Whilst grain boundaries are present between the crystals in the microcrystalline pellet, each microcrystal still contains characteristically few point and line defects. The microcrystalline pellet therefore still contains characteristically few point and line defects due to the slow cooling rate as described hereinabove. In contrast, the nanocrystalline material described in Praveenkumar. P, et al., for instance, will have a higher concentration of grain boundaries, as the nanocrystals have a much smaller size, as well as a higher concentration of point and line defects within the grains due to the method of crystal growth. Whilst the microcrystalline pellet has an increased concentration of defects compared to a single crystal, as a result of any air gaps and/or grain boundaries between the microcrystals, the microcrystalline pellet still has a characteristically low concentration of defects overall due to the high crystallinity and low concentration of point and line defects of the constituent microcrystals.

An advantage of the microcrystalline pressed pellet is that it may easily be formed into any shape and size as is required. The shape and size of the pressed pellet can therefore be easily suited to any shape or size of panel for an X-ray detector. Furthermore, the size of microcrystalline pressed pellet is theoretically limitless and so the microcrystalline pressed pellet is suited to larger scale panels for X-ray detectors. Larger BiOI microcrystalline pressed pellets are also convenient for scaled up production as they may be prepared from smaller sized BiOI single crystals. Larger BiOI single crystals require longer time periods to prepare, thus BiOI microcrystalline pressed pellets of comparable or larger size may be more rapidly prepared.

In another aspect, the present invention provides a BiOI microcrystalline pressed pellet prepared or preparable by the methods described herein.

In another aspect, the present invention provides a panel for an X-ray detector comprising wherein the BiOI single crystal material is a pressed pellet comprising BiOI microcrystals, the BiOI microcrystals having a median particle size diameter (d50) of from 1 μm to 1000 μm.

In another aspect, the present invention provides a panel for an X-ray detector comprising bismuth oxyiodide (BiOI) in the form of BiOI microcrystals formed from a BiOI single crystal, said microcrystals having a median particle size diameter (d50) of from 1 μm to 1000 μm. In some embodiments, the BiOI microcrystals are provided in the form of a pressed pellet.

In another aspect, the invention provides a method for preparing a panel for an X-ray detector, said method comprising depositing first and second electrodes onto a BiOI single crystal material, or a material derived therefrom, for example, wherein the BiOI single crystal material, or a material derived therefrom, is as defined herein. As discussed above, methods of depositing a first and second electrode onto the BiOI single crystal material or a material derived therefrom are known in the art.

In a preferred embodiment, the electrodes are thin film electrodes having a thickness of from 10 nm to 10000 nm, more preferably from 50 nm to 1000 nm, more preferably 100 nm to 200 nm. In a preferred embodiment, the electrodes are gold electrodes, more preferably gold thin film electrodes having a thickness of from 10 nm to 10000 nm, more preferably from 50 nm to 1000 nm, more preferably from 100 nm to 200 nm.

Typically, the method further involves the step of cleaning the BiOI single crystal material, or a material derived therefrom, with a polar organic solvent and evaporating the solvent prior to depositing first and second electrodes. Typically, the organic solvent is an alcohol, such as methanol, ethanol, propanol, isopropanol, butanol, etc, preferably isopropanol. However, other polar organic solves may be used such as THF, diethyl ether, chloroform, dichloromethane, ethyl acetate, acetone, DMF, acetonitrile, nitromethane, or propylene carbonate.

In one embodiment, the method for preparing a panel for an X-ray detector comprises depositing a first and second electrode onto the top and bottom surfaces of a BiOI single crystal material (perpendicular configuration). In an alternative embodiment, the method for preparing a panel for an X-ray detector comprises depositing a first and second electrode onto opposite sides of the front surface of a BiOI single crystal material (parallel configuration).

In the embodiment, where the first and second electrodes are deposited onto opposite sides of the front surface of the BiOI single crystal material, the first and second electrodes may, for example, be deposited on a single surface of the BiOI single crystal material in the form of interdigitated electrodes.

In yet another aspect, the present invention relates to an X-ray detector comprising a panel as described herein.

The X-ray detector may comprise one panel as described herein, or may comprise an array of panels as described herein.

In yet another aspect, the present invention provides a method of detecting X-rays, said method comprising the steps of:
i) providing an X-ray detector as described herein; and
ii) exposing the X-ray detector to a source of X-rays.

The source of X-rays may be any device that emits X-ray radiation, i.e., an X-ray generator, for example, an X-ray tube. The X-ray generator may be a single phase, three phase, constant potential, or high frequency X-ray generator, and X-rays may be generated in either a continuous or a pulsed mode.

In some embodiments, the X-ray source is a collimated beam, X-ray beams may be collimated by a number of processes, for instance by means of a collimator, for example, a parallel hole collimator, a slant-hole collimator, a converging collimator, a fanbeam collimator, or a pinhole collimator. X-ray beams may be collimated during medical imaging to reduce the volume of the patient's tissue that is irradiated. X-ray collimation may additionally reduce stray photons that negatively impact the quality of the medical image.

In some embodiments, the method further comprises an imaging step and formation of a radiograph (e.g. a digital radiograph).

In yet another aspect, the present invention provides use of a BiOI single crystal material, or a material derived therefrom, for the detection of X-rays.

The invention will now be described by reference to the following non-limiting Examples and the Figures.

### EXAMPLES

### Example 1-Preparation of Single Crystals of BiOI

Single crystals of BiOI were obtained through chemical vapour transport in sealed ampoules. As a source, a 1:1 ratio Bi₂O₃:BiI₃ pressed pellet was used. 1.18 g BiI₃ (Sigma Aldrich, 99.99% pure (trace metal basis)) and 0.93 g Bi₂O₃ (Sigma Aldrich, 99.99% pure (trace metal basis)) were pressed into a pellet with a hydraulic press providing 10 tons pressure on a circular chuck with a 0.8 cm diameter. The pressed pellet was transferred to an ampoule with an outer diameter of 15 mm and an inner diameter of 12 mm. The inside of the ampoule was covered by a sheet of paper to prevent powder detaching from the pellet and evaporating off during sealing. The ampoule was evacuated and refilled with argon three times and finally evacuated to a pressure of 0.1 Pa. Using a flame torch the ampoule was sealed under vacuum. The trace moisture present in the ampoule was sufficient to act as a transport agent. The sealed ampoule is placed inside a two-zone furnace where the left and right side of the furnace can independently be controlled. The source zone was heated to 720° C. with a ramp up rate of 1° C./min. The growth zone was heated to 680° C. with a ramp up rate of 2° C./min. Once the final temperatures were reached the temperature was kept constant for roughly three days to let the crystals grow. After three days the crystals were left to cool down with a cooling rate of 0.1° C./min. The ampoule was opened using an electrical circle saw and the BiOI single crystals retrieved.

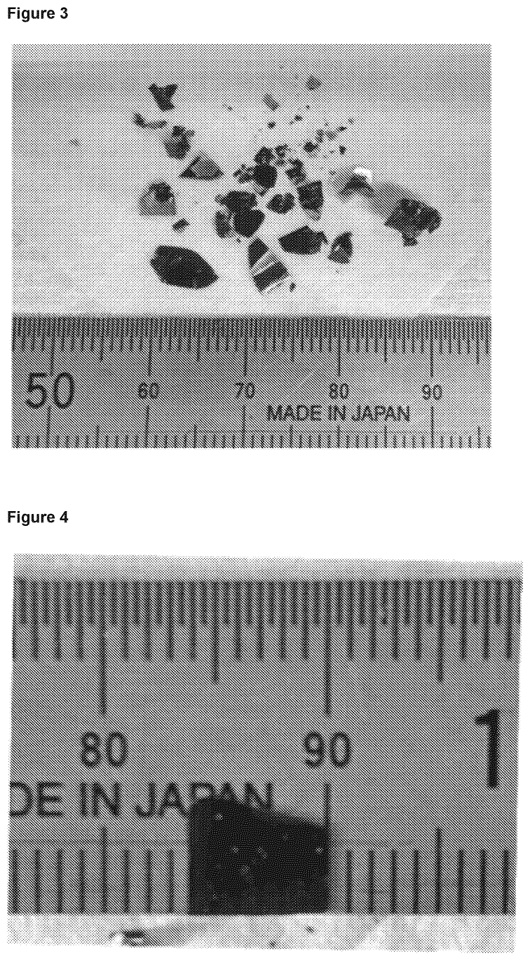

Examples of BiOI single crystals prepared by this method can been seen in FIGS. 3 and 4. In FIGS. 3 and 4 the crystals prepared by the general method of Example 1 are depicted to scale vs a standard ruler to demonstrate their dimensions. The graduation marks on the ruler (labelled 50, 60, 70, 80, and 90 in FIG. 3; and 80 and 90 in FIG. 4, represent mm). As can be seen from these figures, the single crystals prepared by this method may have widths and lengths of greater than 1 mm, with some crystals having widths and lengths of greater than 5 mm. Even larger crystals may be prepared using a larger growth vessel over longer periods of time.

The above method was repeated with varied heating and cooling regimes as is set out in Table 1 below. The above described heating and cooling regime corresponds to batch number 5 in Table 1.

TABLE 1
Preparation Single Crystals of BiOl Under Various Conditions

| | Source | Growth | | | | |
|---|---|---|---|---|---|---|
| Batch | Zone Temp. | Zone Temp. | Transport | Crystal | Growth | Cooling |
| No. | (° C.) | (° C.) | Rate (mg/h) | Size (μm) | Time (h) | Time (h) |
| 1 | 650 | 450 | 1.59 | 50-100 | 116 | 2 |
| 2 | 725 | 600 | 2.18 | 100-300 | 71 | 2 |
| 3 | 725 | 650 | 2.18 | 1000-2000 | 92 | 6 |
| 4 | 720 | 680 | 1.23 | 3000-4000 | 118 | 6 |
| 5 | 720 | 680 | 1.67 | 3000-4000 | 118 | 117 |
| 6 | 720 | 695 | 0.33 | 200-400 | 122 | 6 |

Batch number 5 was cooled from 720° C. to 20° C. over a period of 117 hours, giving a cooling rate of 0.1° C./min. Batches 1 to 4 and 6 were all cooled at a much more rapid rate. The effect of the cooling rate on the crystallinity, e.g., the concentration of point defects and line defects is determined by measuring the below band gap absorption and fitting the Urbach energy.

The absorption profile for the crystals produced in comparative batch 2 are compared to the absorption profile of the crystal produced in batch 5 was determined using photothermal deflection spectroscopy, at 25° C., the results are shown in FIG. 6. The lower absorption in the sub-bandgap photon energy range for the BiOI crystals grown with a slower cooling rate shows the trap density within the bandgap to be smaller. This is because traps in the bandgap would lead to sub-bandgap absorption and light scattering. The sharpness of the absorption onset can be quantified by the Urbach energy using the equation: α=α₀ exp (−[hv−E_{g}]/E_{U}), where α is the absorption coefficient, hv the photon energy, E_{g} the bandgap and E_{U} the Urbach energy. A higher Urbach energy is correlated with a shallower absorption onset. As defects contribute towards absorption, the clean absorption onset observed in the case of slow cooling as compared to the jagged onset of absorption seen in the case of fast cooling, as seen in FIG. 6, further evidences the reduction of defects enjoyed by the BiOI single crystal material of the present invention.

The phase purity of batch 5 is confirmed using XRD as is depicted in FIG. 5. This figure shows that only the (00k) reflections are present. Some additional peaks appeared which were due to reflections from the sample holder (background), as confirmed by running an XRD experiment without sample holder. X-ray diffraction was performed using a Bruker D8 theta/theta system. Cu Ka radiation (I=1.5406 Å) was used as the X-ray source.

### Example 2-Preparation of Single Crystal of BiOI

0.5897 g of BiI₃ (Sigma Aldrich, 99.99% pure (trace metal basis)) and 0.46596 g Bi₂O₃ (Sigma Aldrich, 99.99% pure (trace metal basis)) were pressed into a pellet together with 18 μl of deionised water. The pellet was placed in an ampoule, and the ampoule evacuated to 10 Pa and refilled with argon 3 times. The ampoule was evacuated to 0.01 Pa and sealed with a flame torch. The ampoule was placed in a two-zone furnace and the source zone, containing the pellet was heated to 720° C. while the growth zone was heated to 680° C., both zones were heated with a ramp up rate of 1° C./min. These temperatures were maintained for approximately 120 hours. The ampoule was then cooled at a rate of 0.1° C./min over approximately 5 days. The resulting BiOI single crystals were rinsed with isopropanol and dried in a high vacuum chamber of a thermal evaporator for 2 hours. The resulting BiOI single crystals had dimensions of 1 to 5 mm×1 to 5 mm×0.05 to 2 mm, with the flat reflecting surface corresponding to the (00c) direction as can be seen from X-ray diffraction. The BiOI single crystals had near 100% below bandgap transmission, measured without an integrating sphere. The optical interference fringes in the bandgap transmission indicate a high crystal quality and smoothness.

### Example 3-BiOI Single Crystal Properties

### Resistivity

The resistivity of the BiOI single crystals prepared in Example 2 were measured with electrodes arranged in both the parallel and perpendicular configurations relative to the single crystal material as described hereinbefore. The resistivity was found to be 1.1×10¹² Ω2 cm when the electrodes were arranged in the perpendicular configuration, and the resistivity was found to be 1.8×10⁹ Ω cm when the electrodes were arranged in the parallel configuration.

### Mobility

The photo response upon X-ray illumination of a BiOI single crystal prepared by the method of Example 2 was measured with electrodes arranged in both the perpendicular and parallel configurations relative to the single crystal material as described hereinbefore. A Cu anode X-ray tube with a maximum X-ray energy of 35 KeV and peak intensity of 8 KeV was used to illuminate the BiOI single crystal. The dose rate was calibrated using an X-ray dose meter.

Time of flight measurements were performed to measure carrier mobilities with electrodes in the parallel and perpendicular positions. Selective illumination and changing the bias polarity facilitates the measurement of electron and hole mobility. At low bias voltage, the maximum perpendicular mobility was found to be 26 cm² V⁻¹ s⁻¹, and the maximum parallel mobility was found to be 83 cm² V⁻¹ s⁻¹. Using space-charge limited current density measurements (conducted as is, for instance, described in Saidaminov, M., Abdelhady, A., Murali, B. et al. High-quality bulk hybrid perovskite single crystals within minutes by inverse temperature crystallization. Nat Commun 6, 7586 (2015)), a low trap state density of 2.3×10⁹ cm⁻³ was determined, which is similar to or lower than other state of the art materials such as Cs₂AgBiBr₆, Cs₃Bi₂I₉, and MaPbI₃. The large lifetime mobility product gives rise to diffusion lengths of ˜0.6 μm, and drift lengths capable of reaching 9 mm at 14 V cm⁻¹ applied bias. As would be appreciated, a large lifetime mobility product is needed to achieve a long drift length and therefore extract carriers under low electric fields.

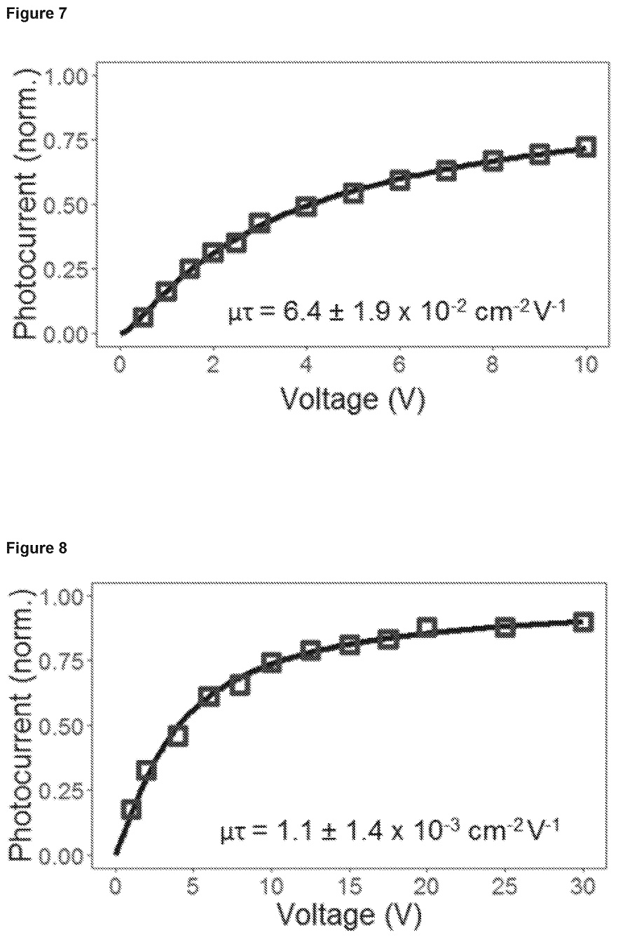

From the voltage dependent photocurrent response of the BiOI single crystal with electrodes, the following mobility-lifetime products (μτ) were determined. μτₚₐᵣₐₗₗₑₗ=6.4±1.9×10⁻² cm⁻² V⁻¹ and μτ_{perpendicular}=1.1±1.4×10⁻³ cm⁻² V⁻¹. The voltage dependent photocurrent response (normalised) of BiOI single crystal with electrodes in the parallel and perpendicular orientation are shown in FIGS. 7 and 8, respectively. The BiOI single crystal prepared in Example 2 was determined to have trap state density of 2.3×10⁹ cm⁻³, as determined through space-charge limited current density measurements.

### Sensitivity

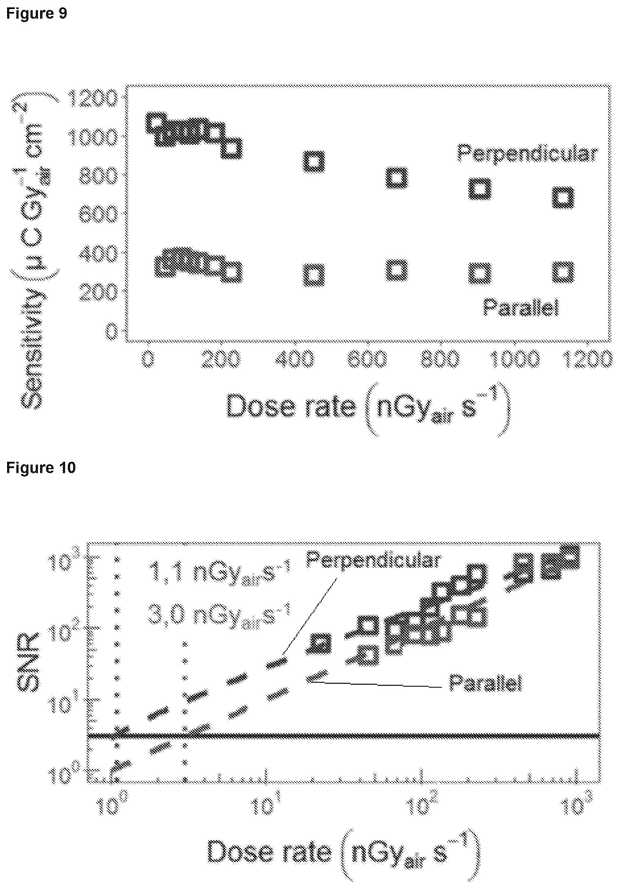

The maximum measured sensitivity was 1067 μC Gyₐᵢᵣ 1 cm⁻² with electrodes in the perpendicular orientation and 372 μC Gyₐᵢᵣ 1 cm⁻² electrodes in the parallel orientation. The sensitivities of the BiOI single crystal with electrodes in the parallel and the perpendicular positions at varying dose rate (nGyₐᵢᵣ s⁻¹) are shown in FIG. 9. As can be seen, a good sensitivity is maintained in both positions at various X-ray dosage. The sensitivity was measured by determining the change in the photocurrent from the detectors both with and without illumination by the X-ray source.

### Lowest Detectable Dose

The estimated minimum detectable dose rate (LoDD) was 1.1 nGyₐᵢᵣs⁻¹ with electrodes in the perpendicular orientation and 3.0 nGyₐᵢᵣs⁻¹ with electrodes in the parallel orientation. These results are shown in FIG. 10. The LoDD was determined by measuring the photocurrent of the detectors over a range of X-ray dose rates and extrapolating the photocurrent down to find the intersection with a current that is three times the dark current.

As would be appreciated, these LoDD are up to an order of magnitude lower than those of previously known X-ray detectors and several orders of magnitude lower than what is required for standard medical imaging.

### Urbach Energy

Transmittance measurements using ultraviolet-visible spectrophotometry (with optical interference effects precisely accounted for) were used to estimate the Urbach energy. Ultraviolet-visible spectrophotometry was conducted, utilising a tungsten white light source and diffraction grating to measure the transmittance. A BiOI crystal prepared as per Example 2 was mounted inside a vacuum-cryostat (base pressure 0.01 Pa) onto a helium cooled cold finger with 1 mm diameter openings. A transfer matrix model was developed and fit to the measured transmittance to account for interference effects between transmitted and reflected light from the two BiOI/vacuum interfaces. The Urbach energy of the BiOI crystal was estimated to be 45 meV.

### Dark Current Density

Dark current measurements were measured with electrodes in the perpendicular orientation and with electrodes in the parallel orientation. FIG. 11 depicts the current-Voltage curve for both the parallel and perpendicular device configurations. The resistivity values are also depicted in FIG. 11. FIG. 12 depicts dark current values at different applied bias voltages over time. It can be seen that the dark current remained stable over time over a range of voltages.

Comparison of BiOI Single Crystal Properties with Known Semiconductor X-Ray Detector Materials

Table 2 below outlines various properties relevant to X-ray detection for BiOI single crystals with electrodes in the parallel configuration and in the perpendicular configuration, compared with literature values for known X-ray detecting materials.

TABLE 2
Comparison of the key properties and performance of semiconductor X-ray detector materials

| | | | | | BiOl | BiOl |
|---|---|---|---|---|---|---|
| | a-Se * | Hgl₂ * | CZT * | MAPbBr₃ * | parallel ** | perpendicular ** |
| Band gap (eV) | 2.2 | 2.1 | 1.5-1.6 | 2.2 | 1.93 | 1.93 |
| Atomic number | 34 | 80.53 | 48.52 | 35.82 | 73.6 | 73.6 |
| μT product (cm² V⁻¹) | 10⁻⁷ | 1.5 × 10⁻⁵ | 4 × 10⁻³-10⁻² | 1.2 × 10⁻² | 6.4 × 10⁻² | 1.1 × 10⁻³ |
| Sensitivity | 20 | 1600 | 318 | 2.1 × 10⁴ | 372 | 1100 |
| (μC Gyₐᵢᵣ⁻¹cm⁻²) | | | | | | |
| Lowest detectable | 5.5 | 10 | 50 | 0.036 | 0.003 | 0.0011 |
| dose (μGyₐᵢᵣs⁻¹) | | | | | | |
| Dark current | 0.1-8 (10 V | 10 (0.25 V | 90 (0.25 V | 230 (0.5 mV | 25 (0.5 mV | 0.5 (5.5 V |
| density (pA mm⁻²)^{a} | μm⁻¹) | μm⁻¹) | μm⁻¹) | μm⁻¹) | μm⁻¹) | μm⁻¹) |
| References | 1, 2, 8 | 7, 9 | 3, 4, 10 | 5, 6 | This work | This work |

^{a}Electric field used for measuring the dark current reported shown in brackets
* Comparative example
** Of the invention

### REFERENCES FOR TABLE 2

[1] Kasap, S. O. X-ray sensitivity of photoconductors: application to stabilized a-Se. J. Phys. D 33, 2853 (2000).
[2] David, M. H., Belev, G., Kasap, S. & Martin, J. Y., Measured and calculated K-fluorescence effects on the MTF of an amorphous-selenium based CCD x-ray detector. Med. Phys. 39, 608-622 (2012).
[3] Ivanov, Yu, M. et al. The possibilities of using semi-insulating CdTe crystals asdetecting material for X-ray imaging radiography. Phys. Stat. Sol. C 0, 840-844 (2003).
[4] Bellazzini, R. et al. Chromatic X-ray imaging with a fine pitch CdTe sensorcoupled to a large area photon counting pixel ASIC. J. Instrum. 8, C02028 (2013).
[5] Wei, H. et al. Sensitive X-ray detectors made of methylammonium lead tribromide perovskite single crystals. Nat. Photon 10, 333 (2016).
[6] Wei, W. et al. Monolithic integration of hybrid perovskite single crystals with heterogenous substrate for highly sensitive X-ray imaging. Nat. Photon 11, 315 (2017).
[7] Zentai, G. et al. Mercuric iodide and lead iodide x-ray detectors for radiographic and fluoroscopic medical imaging. Medical Imaging 2003, San Diego, United States, 15 (SPIE).
[8] Kasap, S. et al. Amorphous selenium and its alloys from early xeroradiography to high resolution x-ray image detectors and ultrasensitive imaging tubes. Phys. Status Solidi B Basic Solid State Phys. 246, 1794-1805 (2009); and references therein.
[9] Du, H. et al. Investigation of the signal behavior at diagnostic energies of prototype, direct detection, active matrix, flat-panel imagers incorporating polycrystalline Hgl2. Phys. Med. Biol. 53, 1325-1351 (2010).
Tokuda, S.; Kishihara, H.; Adachi, S.; Sato, T. Preparation and characterization of polycrystalline CdZnTe films for large-area, high-sensitivity X-ray detectors. J. Mater. Sci. Mater. Electron. 5, 1-8 (2004).

### Example 4-Preparation of an X-Ray Detector of the Present Invention

After growing the BiOI single crystals using the procedure detailed in Example 2, the crystals were rinsed in isopropanol. Subsequently the crystals were transferred to a thermal evaporator, which was pumped down to high vacuum (<0.001 Pa base pressure) and dried for 2 h. 100 nm Au was evaporated onto the crystals through a shadow mask to define the area of the electrodes. This was repeated on the opposite [00c] face of the crystals for the perpendicular device configuration.

1. A panel for an X-ray detector comprising a bismuth oxyiodide (BiOI) single crystal material.

2. A panel for an X-ray detector comprising bismuth oxyiodide (BiOI) in the form of BiOI microcrystals formed from a BiOI single crystal, said microcrystals having a median particle size diameter (d50) of from 1 μm to 1000 μm.

3. A panel according to claim 1, wherein the single crystal material comprises one or more BiOI single crystals having a length (L) dimension of at least 1 mm, a width (W) dimension of at least 1 mm, and a thickness (T) dimension of at least 0.05 mm.

4. A panel according to claim 3, wherein L is from 1 to 1000 mm; W is from 1 to 1000 mm; and T is from 0.05 to 10 mm; preferably wherein L is from 2 to 500 mm; W is 2 to 500 mm, and T is 0.06 to 0.14 mm.

5. A panel according to claim 1, wherein the single crystal material, or BiOI microcrystals, have at least any one of: a trap-state density below 10¹⁰ cm⁻³, as determined through space-charge limited current density measurements; a mobility-lifetime product of at least 3.0×10⁻² cm² V⁻¹, preferably at least 5.0×10⁻² cm² V⁻¹; and/or an X-ray sensitivity of >500 μC Gy lair cm⁻², preferably an X-ray sensitivity of >1000 μC Gy⁻¹ₐᵢᵣ cm⁻².

6. A panel according to claim 1, wherein the single crystal material, or BiOI microcrystals, have a lowest detectable dose (LoDD) rate for Cu K_{α} X-rays from 1 to 5 nGyₐᵢᵣ s⁻¹, preferably from 1 to 3 nGyₐᵢᵣ s⁻¹.

7. A bismuth oxyiodide (BiOI) single crystal material for use in a panel for an X-ray detector having a length (L) dimension of at least 1 mm, a width (W) dimension of at least 1 mm, and a thickness (T) dimension of at least 0.12 mm, optionally wherein the single crystal material is as defined in claim 5.

8. A bismuth oxyiodide (BiOI) single crystal material for use in a panel for an X-ray detector, the BiOI single crystal material having:
an Urbach energy, determined by measurement of the transmittance by ultraviolet-visible spectrophotometry, of 50 meV or lower, preferably 48 meV or lower, more preferably 46 meV or lower; and/or
a trap state density, as determined through space-charge limited current density measurements, below 10¹⁰ cm⁻³, preferably below 5×10⁹ cm⁻³, more preferably below 3×10⁹ cm⁻³.

9. A bismuth oxyiodide (BiOI) microcrystal material for use in a panel for an X-ray detector, wherein the BiOI microcrystal material is a pressed pellet comprising BiOI microcrystals, the BiOI microcrystals having a median particle size diameter (d50) of from 1 μm to 1000 μm.

10. A vapour phase crystal growth method for preparing a BiOI single crystal material, said method comprising the steps:
i) providing powders of BiI₃ and Bi₂O₃ together with a transport agent in a sealable growth chamber;
ii) evacuating air from inside the growth chamber, filling the growth chamber with an inert gas, and sealing the growth chamber to form a sealed growth chamber;
iii) heating the contents of the growth chamber to a temperature between 500° C. and 750° C. and maintaining the temperature within this range for at least 48 hours; and
iv) cooling the contents of the growth chamber at a rate of 1° C./min or less.

11. A method for preparing a BiOI microcrystalline pressed pellet for use in a panel for an X-ray detector, said method comprising steps i) to iv) as defined in claim 10, followed by the following further steps:
v) crushing the BiOI single crystal material into a powder having a median particle size diameter (d50) of from 1 μm to 1000 μm; and
vi) pressing, and optionally sintering, the powder into a pellet to form a BiOI microcrystalline pressed pellet.

12. A method according to claim 10, wherein the BiI₃ and Bi₂O₃ powders, together with the transport agent, are provided in the form of a compressed pellet in step i).

13. A method according to claim 10, wherein the growth chamber used is an ampoule that is sealed using a flame torch.

14. A method according to claim 10, wherein the transport agent is selected from H₂O, H₂, I₂, Br₂, Cl₂, Se, SeCl₄ and TeCl₄, preferably wherein the transport agent is selected from H₂O, Cl₂, Br₂, and I₂, most preferably wherein the transport agent is H₂O.

15. A method according to claim 10, wherein heating in step iii) is in a two-zone reactor, wherein the two zones have different temperatures and include a first source zone having a relatively higher temperature and second growth zone having a relatively lower temperature, preferably wherein the difference in temperature between the two zones is at least 40° C.

16. A method according to claim 10, wherein the temperature in the growth zone is maintained at from 500° C. to 700° C., preferably from 670° C. to 690° C., for example from 675° C. to 685° C.; and/or wherein the temperature in the source zone is maintained at from 700° C. to 750° C., preferably from 710° C. to 730° C., for example from 715° C. to 725° C.

17. A bismuth oxyiodide (BiOI) single crystal material prepared, or preparable, by the method of claim 10.

18. A bismuth oxyiodide (BiOI) microcrystalline pressed pellet prepared, or preparable, by the method of claim 11.

19. A method for preparing a panel for an X-ray detector, said method comprising depositing first and second electrodes onto a BiOI single crystal material, or a material derived therefrom, for example, wherein the BiOI single crystal material is as defined in claim 3 or wherein the BiOI single crystal material is; or wherein the material derived the BiOI single crystal material is as defined or wherein the material derived the BiOI single crystal material is.

20. A method according to claim 19, wherein the method comprises a step of cleaning the BiOI single crystal material or material derived therefrom with a polar organic solvent and evaporating the solvent prior to depositing first and second electrodes.

21. A method according to claim 19, wherein first and second electrodes are deposited on a single surface of the BiOI single crystal material (e.g. in the form of interdigitated electrodes).

22. A method according to claim 19, wherein first and second electrodes are separately deposited on opposing top and bottom surfaces of the BiOI single crystal material in a thickness direction.

23. An X-ray detector comprising a panel according to claim 1.

24. A method of detecting X-rays, said method comprising the steps of:
i) providing an X-ray detector according to claim 23; and
ii) exposing the X-ray detector to a source of X-rays.

25. Use of a bismuth oxyiodide (BiOI) single crystal material, or material derived therefrom, for the detection of X-rays.
